(19) United States
(12) Patent Application Publication
(10) Pub. No.: US 2023/0324129 A1
(43) Pub. Date: Oct. 12, 2023

(54) COOLING DEVICE

(71) Applicant: Nidec Corporation, Kyoto (JP)

(72) Inventors: Kazuhiro NISHIKAWA, Kyoto (JP); Yuta HORI, Kyoto (JP); Kengo INOUE, Kyoto (JP)

(21) Appl. No.: 18/129,954

(22) Filed: Apr. 3, 2023

(30) Foreign Application Priority Data
Apr. 7, 2022 (JP) 2022-063935

(51) Int. Cl. F28D 15/00; F28F 13/12; F28F 3/02

(52) U.S. Cl. CPC F28D 15/00; F28F 13/125; F28F 3/02; F28F 2215/10

(57) ABSTRACT

A cooling device includes a heat dissipator and a liquid cooling jacket. The heat dissipator includes a plate-shaped base portion that extends in a first direction along a direction where a refrigerant flows and in a second direction orthogonal to the first direction and has a thickness in a third direction, a fin that protrudes from the base portion to one side in the third direction, and a top plate portion provided to an end of the fin. The liquid cooling jacket includes a top surface located on one side of the top plate portion with a gap between the top surface and the top plate portion. Top surface recesses recessed from the top surface toward one side and located side by side in the first direction.

### CROSS-REFERENCE TO RELATED APPLICATIONS

The present application claims priority under 35 U.S.C. § 119 to Japanese Patent Application No. 2022-063935, filed on Apr. 7, 2022, the entire contents of which are hereby incorporated herein by reference.

### 1. FIELD OF THE INVENTION

The present disclosure relates to a cooling device.

### 2. BACKGROUND

Conventionally, a cooling device is used for cooling a heating element. A cooling device includes a heat dissipator and a liquid cooling jacket. The heat dissipator includes a base portion and a plurality of fins. The plurality of fins protrude from the base portion. A flow path is formed by the heat dissipator and the liquid cooling jacket. When a refrigerant flows through the flow path, the heat of the heating element moves to the refrigerant.

As described above, when the flow path is formed by the liquid cooling jacket and the heat dissipator, it is necessary to provide a certain gap (clearance) between the fin and the liquid cooling jacket. If there is no gap, the fin may be deformed when the base portion is attached to the liquid cooling jacket, and desired cooling performance may not be secured. In addition, there is a possibility that the fin cannot be accommodated in the liquid cooling jacket due to positional variation when the fin is fixed to the base portion or assembly tolerance of the fin.

For this reason, a certain gap is provided in advance between the fin and the liquid cooling jacket. However, when a large amount of the refrigerant flows in this gap, an inflow amount of the refrigerant between the fins decreases, and there arises a problem that the ability to cool the fins by the liquid decreases.

### SUMMARY

An example embodiment of a cooling device of the present disclosure is a cooling device that includes a heat dissipator and a liquid cooling jacket. The heat dissipator includes a plate-shaped base portion that extends in a first direction along a direction where a refrigerant flows and in a second direction orthogonal to the first direction and has a thickness in a third direction orthogonal to the first direction and the second direction, a fin that protrudes from the base portion to one side in the third direction, and a top plate portion provided to an end on one side in the third direction of the fin. The liquid cooling jacket includes a top surface located on one side in the third direction of the top plate portion with a gap in the third direction between the top surface and the top plate portion, and top surface recesses recessed from the top surface toward one side in the third direction and located side by side in the first direction.

The above and other elements, features, steps, characteristics and advantages of the present disclosure will become more apparent from the following detailed description of the example embodiments with reference to the attached drawings.

### BRIEF DESCRIPTION OF THE DRAWINGS

FIG. 1 is an exploded perspective view of a cooling device according to an example embodiment of the present disclosure.

FIG. 2 is a side sectional view of a cooling device according to an example embodiment of the present disclosure.

FIG. 3 is a perspective view of a heat dissipator according to an example embodiment of the present disclosure.

FIG. 4 is a partially enlarged view of the configuration of the side section illustrated in FIG. 2.

FIG. 5 is a perspective view showing a configuration of a liquid cooling jacket according to a first modification of an example embodiment of the present disclosure.

FIG. 6 is a partial side sectional view of a cooling device according to a second modification of an example embodiment of the present disclosure.

FIG. 7 is a partial side sectional view of a cooling device according to a third modification of an example embodiment of the present disclosure.

FIG. 8 is a perspective view illustrating a configuration of a liquid cooling jacket according to a fourth modification of an example embodiment of the present disclosure.

FIG. 9 is an enlarged perspective view illustrating an example configuration of a single spoiler of an example embodiment of the present disclosure.

### DETAILED DESCRIPTION

Hereinafter, example embodiments of the present disclosure will be described with reference to the drawings.

In the drawings, with the first direction as an X direction, X1 indicates one side in the first direction, and X2 indicates the other side in the first direction. The first direction is along a direction F in which a refrigerant W flows, and the downstream side is indicated by F1 and the upstream side is indicated by F2. With the second direction orthogonal to the first direction as a Y direction, Y1 indicates one side in the second direction, and Y2 indicates the other side in the second direction. With the third direction orthogonal to the first direction and the second direction as a Z direction, Z1 indicates one side in the third direction, and Z2 indicates the other side in the third direction. Note that the above-described “orthogonal” also includes intersection at an angle slightly shifted from 90 degrees. Each of the above-described directions does not limit a direction when a cooling device 1 is incorporated in various devices.

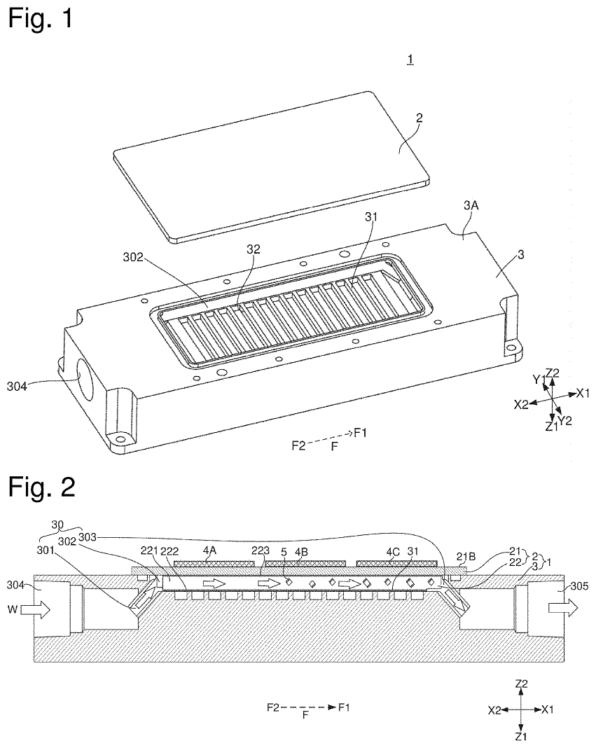

FIG. 1 is an exploded perspective view of the cooling device 1 according to an example embodiment of the present disclosure. FIG. 2 is a side sectional view of the cooling device 1. FIG. 2 is a view illustrating a state of being cut along a section orthogonal to the second direction as viewed from the other side in the second direction to one side in the second direction.

The cooling device 1 includes a heat dissipator 2 and a liquid cooling jacket 3. The heat dissipator 2 is provided to the liquid cooling jacket 3. FIG. 2 illustrates the flow of refrigerant W. One side in the first direction is a downstream side in a direction in which the refrigerant W flows, and the other side in the first direction is an upstream side in the direction in which the refrigerant W flows. The cooling device 1 is a device that cools a plurality of heating elements 4A, 4B, and 4C (hereinafter 4A and the like) with the refrigerant W. The refrigerant W is liquid such as water. That is, the cooling device 1 performs liquid cooling such as water cooling. The number of heating elements may be a plural number other than three, or may be singular.

The liquid cooling jacket 3 is a die-cast product that spreads in the first direction and the second direction and has a thickness in the third direction. The liquid cooling jacket 3 is made of metal such as aluminum. The liquid cooling jacket 3 has a flow path therein for allowing the refrigerant W to flow.

More specifically, the liquid cooling jacket 3 includes a refrigerant flow path 30, an inlet flow path 304, and an outlet flow path 305. The inlet flow path 304 is located at the end on the other side in the first direction of the liquid cooling jacket 3 and is configured of columnar spaces, having different diameters extending in the first direction, arranged in the first direction.

The refrigerant flow path 30 includes a first flow path 301, a second flow path 302, and a third flow path 303. The first flow path 301 has a width in the second direction and is inclined to one side in the first direction and the other side in the third direction. The other end in the first direction of the first flow path 301 is connected to one end in the first direction of the inlet flow path 304. The second flow path 302 has a width in the second direction and extends in the first direction. The other end in the first direction of the second flow path 302 is connected to one end in the first direction of the first flow path 301. The third flow path 303 has a width in the second direction and is inclined to one side in the first direction and one side in the third direction. One end in the first direction of the second flow path 302 is connected to the other end in the first direction of the third flow path 303.

The outlet flow path 305 is located at one end in the first direction of the liquid cooling jacket 3, and is configured of columnar spaces, having different diameters extending in the first direction, arranged in the first direction. One end in the first direction of the third flow path 303 is connected to the other end in the first direction of the outlet flow path 305.

In this manner, the refrigerant W flowing into the inlet flow path 304 flows into the first flow path 301 and flows to one side in the first direction and the other side in the third direction in the first flow path 301, flows into the second flow path 302 and flows to one side in the first direction in the second flow path 302, flows into the third flow path 303 and flows to one side in the first direction and the one side in the third direction in the third flow path 303, and flows into the outlet flow path 305 and is discharged to the outside of the liquid cooling jacket 3.

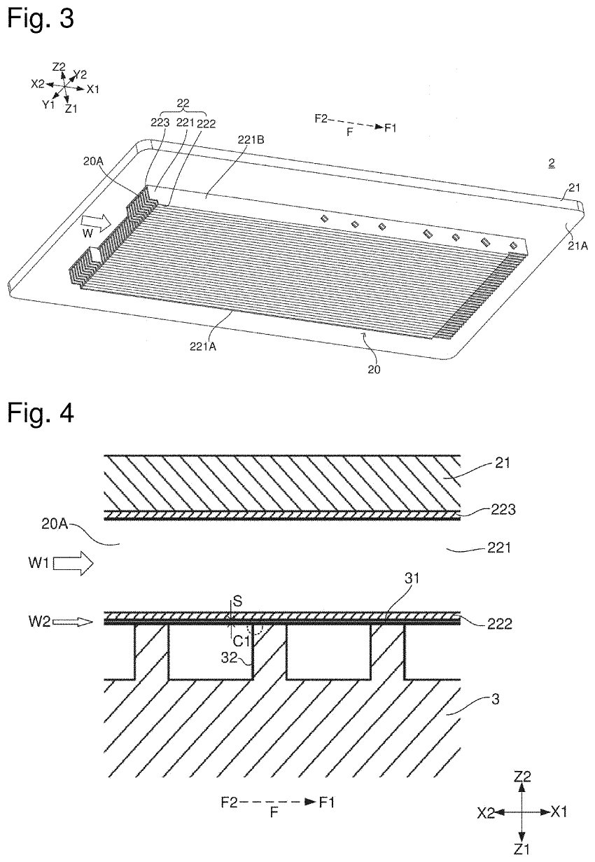

FIG. 3 is a perspective view of a heat dissipator. As described above, the heat dissipator 2 can be installed in the liquid cooling jacket 3, and includes a fin group 20 and a base portion 21.

The base portion 21 has a plate shape that extends in the first direction and the second direction and has a thickness in the third direction. The base portion 21 is made of a metal having high thermal conductivity, for example, a copper plate.

The fin group 20 is configured as so-called stacked fins by stacking a plurality of fins 22 in the second direction. The fin group 20 is fixed to a surface 21A on one side in the third direction of the base portion 21 by brazing or the like. That is, the heat dissipator 2 has the fin group 20 in which the fins 22 are arranged in the second direction.

The fin 22 is formed of one metal plate extending in the first direction. The fin 22 is made of, for example, a copper plate. The fin 22 includes a side plate portion 221, a top plate portion 222, and a bottom plate portion 223. The side plate portion 221 has a flat plate shape that extends in the first direction and the third direction and has a thickness in the second direction.

The top plate portion 222 is bent toward one side in the second direction (that is, second direction) at the one end in the third direction of the side plate portion 221. The bottom plate portion 223 is bent toward one side in the second direction at the other end in the third direction of the side plate portion 221. The top plate portion 222 and the bottom plate portion 223 are formed by press working. Thus, the top plate portion 222 can be easily formed.

The fins 22 having such a configuration are stacked in the second direction to form the fin group 20. The bottom plate portion 223 in the fin group 20 is fixed to the surface 21A on one side in the third direction of the base portion 21. As described above, the heat dissipator 2 includes the fins 22 protruding from the base portion 21 to one side in the third direction, and the top plate portion 222 provided at one end in the third direction of the fin 22.

In the liquid cooling jacket 3, a top surface 31 (see FIG. 1) is formed at one end in the third direction of the second flow path 302. The top surface 31 is a plane extending in the first direction and the second direction.

In a state where the heat dissipator 2 is not attached to the liquid cooling jacket 3, the top surface 31 is exposed to the other side in the third direction. The heat dissipator 2 is attached to the liquid cooling jacket 3 by fixing a surface 21A on one side in the third direction of the base portion 21 in the heat dissipator 2 to a surface 3A on the other side in the third direction of the liquid cooling jacket 3. In a state where the heat dissipator 2 is attached, the other side in the third direction of the top surface 31 is covered with the base portion 21. As a result, the second flow path 302 is closed by the base portion 21. In a state where the heat dissipator 2 is attached to the liquid cooling jacket 3, the fin group 20 is accommodated in the second flow path 302.

The heating element 4A and the like are fixed to a surface 21B (see FIG. 2) on the other side in the third direction of the base portion 21. The heating element 4A and the like are, for example, semiconductor devices. The semiconductor device is a power transistor of an inverter included in a traction motor for driving wheels of a vehicle, for example. The power transistor is, for example, an insulated gate bipolar transistor (IGBT).

The refrigerant W flowing from the first flow path 301 into the second flow path 302 flows to one side in the first direction through a flow path 20A (see FIG. 3) formed between the fins 22 adjacent to each other in the second direction. The flow path 20A extends in the first direction along the side plate portion 221, and is located between the top plate portion 222 and the bottom plate portion 223. The heat generated from the heating element 4A and the like moves to the refrigerant W flowing through the flow path 20A via the base portion 21 and the fins 22, and the heating element 4A and the like are cooled.

FIG. 4 is a partially enlarged view of the configuration of the side section illustrated in FIG. 2. In a state where the heat dissipator 2 is attached to the liquid cooling jacket 3 as described above, the fin group 20 is accommodated in the second flow path 302. At this time, as illustrated in FIG. 4, a gap (clearance) S in the third direction is formed between the top plate portion 222 of the fin 22 and the top surface 31 of the liquid cooling jacket 3. That is, the liquid cooling jacket 3 has the top surface 31 located on one side in the third direction of the top plate portion 222 via a gap S in the third direction between the liquid cooling jacket and the top plate portion 222.

As illustrated in FIG. 4, a refrigerant W1 flows through the flow path 20A between the fins 22, and a refrigerant W2 flows through the gap S. When a large amount of the refrigerant W2 flows into the gap S, the inflow amount of the refrigerant W1 into the flow path 20A between the fins 22 decreases, and the ability to liquid-cool the fins 22 decreases. Therefore, in the present example embodiment, a top surface recess 32 (see also FIG. 1) is provided to the liquid cooling jacket 3.

The top surface recess 32 is formed to be recessed from the top surface 31 toward one side in the third direction. The top surface recess 32 is formed in a rectangular parallelepiped shape extending in the second direction, and a plurality of them are arranged side by side in the first direction. That is, the liquid cooling jacket 3 has the top surface recesses 32 that are recessed toward one side in the third direction from the top surface 31, and are arranged side by side in the first direction.

By providing the top surface recess 32 in the top surface 31 of the liquid cooling jacket 3, a turbulent flow is generated in the refrigerant W2 flowing through the gap S due to a corner portion C1 of the top surface recess 32. As a result, the flow path resistance of the gap S increases. Therefore, the flow rate of the refrigerant W1 flowing through the flow path 20A located on the other side in the third direction of the top plate portion 222 increases, and the cooling performance can be improved. The corner portion C1 may be a chamfered corner portion.

The top surface recess 32 is formed as a groove extending in the second direction. As a result, a turbulent flow is generated in a direction orthogonal to the flow of the refrigerant W2, and the turbulent flow can be expanded in the entire second direction to improve cooling performance.

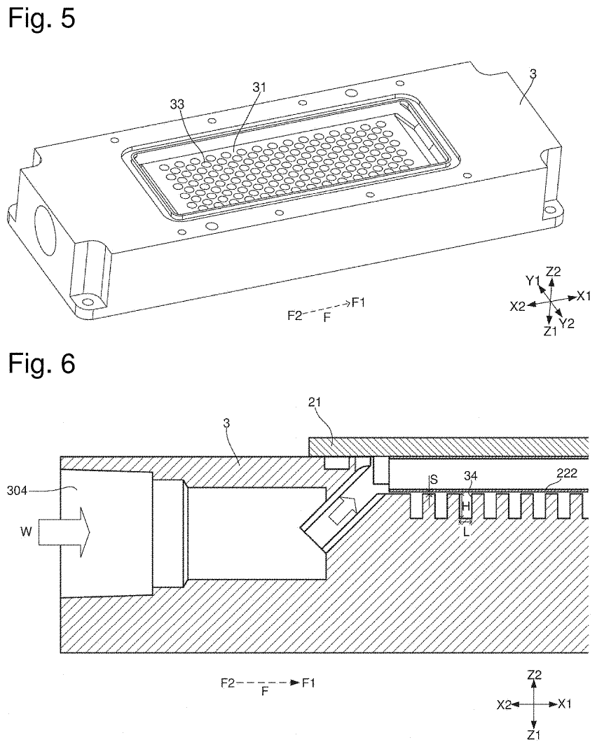

FIG. 5 is a perspective view showing a configuration of a liquid cooling jacket 3 according to a first modification. In the liquid cooling jacket 3 illustrated in FIG. 5, a top surface recess 33 is provided instead of the top surface recess 32 of the above-described example embodiment.

The top surface recess 33 is a columnar space recessed from the top surface 31 toward one side in the third direction. Note that the top surface recess 33 may be a hemispherical or conical space.

That is, the top surface recess 33 is formed in a circular shape as viewed in the third direction. The effect of stirring the refrigerant W in the second direction is obtained by the top surface recess 33. As a result, the low-temperature refrigerant W2 flowing through the flow path not overlapping with the heating element 4A and the like as viewed in the third direction in the gap S and the high-temperature refrigerant W2 flowing through the flow path overlapping with the heating element 4A and the like as viewed in the third direction in the gap S are mixed, and the cooling performance can be further improved. In addition, by stirring the refrigerant W2 flowing through the gap S, the turbulence factor in the second direction can be increased, and the flow path resistance of the gap S can be increased.

FIG. 6 is a partial sectional view of a cooling device 1 according to a second modification. FIG. 6 illustrates an upstream configuration.

In the liquid cooling jacket 3 illustrated in FIG. 6, a top surface recess 34 is provided instead of the top surface recess 32 of the above-described example embodiment. The top surface recess 34 is formed as a groove extending in the second direction similarly to the top surface recess 32, but a depth H in the third direction of the top surface recess 34 is longer than a width L in the first direction of the top surface recess 34. As a result, turbulent flow can be further generated in the gap S, and the flow path resistance of the gap S can be further increased.

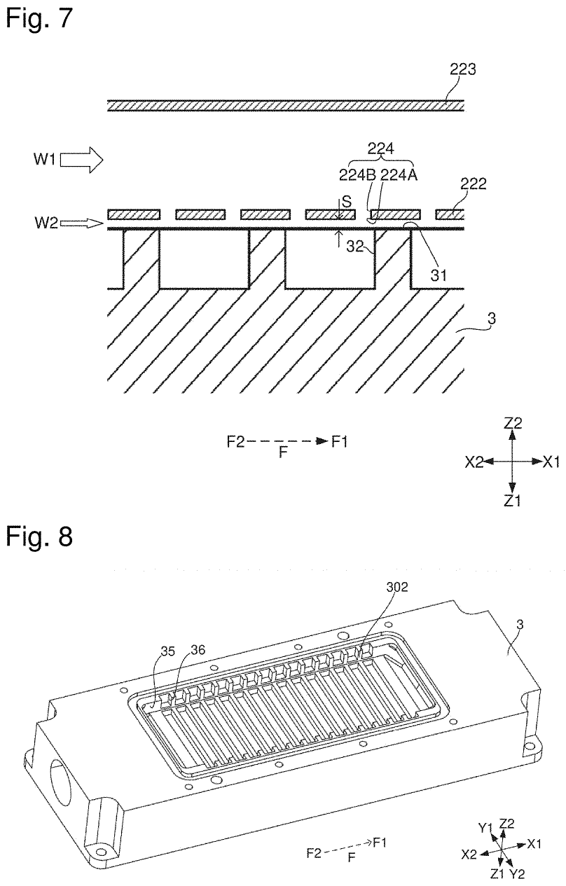

FIG. 7 is a partial sectional view of the cooling device 1 according to a third modification. In the configuration illustrated in FIG. 7, the top plate portion 222 has a slit 224 penetrating in the third direction. The slits 224 are arranged side by side in the first direction.

The slit 224 has a top plate recess 224A and a top plate recess 224B. The top plate recess 224A is recessed from the surface on one side in the third direction of the top plate portion 222 to the other side in the third direction. The top plate recess 224B is recessed from the surface on the other side in the third direction of the top plate portion 222 to one side in the third direction. The top plate recess 224A and the top plate recess 224B are connected to each other in the third direction. The slit 224 is located at a position facing the turbulent flow region generated by the top surface recess 32 in the third direction.

That is, a plurality of top plate recesses 224A that are recessed from the surface on one side in the third direction of the top plate portion 222 to the other side in the third direction and are arranged side by side in the first direction, are provided. The top plate recess 224A is located at a position facing the turbulent flow region generated by the top surface recess 32 in the third direction. As a result, turbulent flow can be further generated in the gap S, and the flow path resistance of the gap S can be further increased.

FIG. 8 is a perspective view illustrating a configuration of a liquid cooling jacket 3 according to a fourth modification. In the liquid cooling jacket 3 illustrated in FIG. 8, the side wall portions 35 are provided at both ends in the second direction of the second flow path 302. In a state where the heat dissipator 2 (see FIG. 3) is attached to the liquid cooling jacket 3 illustrated in FIG. 8, the side plate portion 221A (see FIG. 3) provided at one end in the second direction in the fin group 20 faces the side wall portion 35 on one side in the second direction of the liquid cooling jacket 3 in the second direction. In addition, the side plate portion 221B (see FIG. 3) provided at the other end in the second direction in the fin group 20 faces the side wall portion 35 on the other side in the second direction of the liquid cooling jacket 3 in the second direction.

As illustrated in FIG. 8, the side wall portion 35 on one side in the second direction is provided with a side wall recess 36 recessed to one side in the second direction. The side wall portion 35 on the other side in the second direction is provided with a side wall recess 36 recessed toward the other side in the second direction. The side wall recesses 36 are arranged side by side in the first direction.

That is, the liquid cooling jacket 3 includes the side wall portion 35 facing, in the second direction, the side plate portions 221A and 221B arranged at both ends in the second direction of the fin group 20, and the side wall recesses 36 recessed in the second direction in the side wall portions 35 and arranged side by side in the first direction. As a result, a turbulent flow occurs in the gap between the side wall portion 35 and the side plate portions 221A and 221B due to the corners of the side wall recess 36, and the flow path resistance on both outer sides in the second direction of the fin group 20 increases. Therefore, the flow rate of the refrigerant W flowing into the fin group 20 increases, and the cooling performance can be improved.

As illustrated in FIG. 2, the fin 22 is provided with a spoiler 5. Here, the spoiler 5 will be described in detail.

In the configuration illustrated in FIG. 2, a single spoiler in which only one spoiler 5 is provided is formed in the arrangement region of the heating element 4B on the upstream side, and a double spoiler in which two spoilers 5 are provided is also formed in addition to the single spoiler in the arrangement region of the heating element 4C on the downstream side.

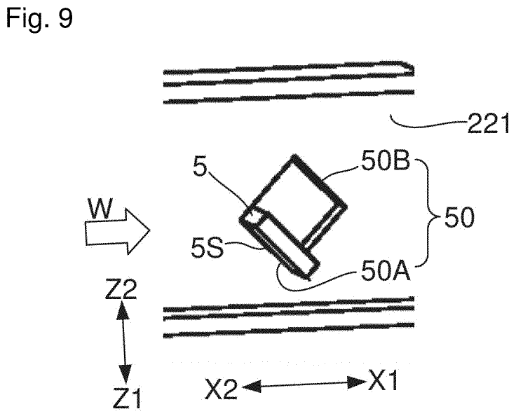

FIG. 9 is an enlarged perspective view illustrating an exemplary configuration of a single spoiler. A through hole 50 penetrates the side plate portion 221 of the fin 22 in the second direction. The through hole 50 has a rectangular shape. The through hole 50 has a pair of opposing sides 50A and 50B inclined to one side in the first direction and one side in the third direction. The side 50A is positioned on the other side in the first direction relative to the side 50B. The spoiler 5 is formed by being bent to one side in the second direction on the side 50A. The through hole 50 and the spoiler 5 can be formed by making a cut in the side plate portion 221.

The spoiler 5 includes an opposing surface 5S facing the direction in which the refrigerant W flows, that is, one side in the first direction. The spoiler 5 has a function of preventing the flow of the refrigerant W by the opposing surfaces 5S. The turbulent flow of the refrigerant W is easily generated in the vicinity of the opposing surface 5S, and the cooling performance by the fin 22 can be improved. The spoiler 5 is inclined to one side in the first direction and one side in the third direction. This makes it possible to guide the refrigerant W to the base portion 21 side by the spoiler 5, and the cooling performance can be improved.

Note that the single spoiler includes a configuration in which the spoiler 5 is provided on the side 50B side, in addition to the configuration illustrated in FIG. 9. In the double spoiler, the spoilers 5 are provided on both the sides 50A and 50B.

As described above, the fin 22 has the spoiler 5 protruding in the second direction from the side plate portion 221. Since the turbulent flow is generated in the vicinity of the spoiler 5, the cooling performance can be further improved.

As illustrated in FIG. 2, three single spoilers, that is, three spoilers 5, are provided in the arrangement region of the heating element 4B. In the arrangement region of the heating element 4C, two single spoilers and two double spoilers are provided, that is, a total of six spoilers 5 are provided.

That is, the number of spoilers 5 increases toward one side in the first direction. As a result, the temperature of the refrigerant W increases, and the cooling performance can be improved on the downstream side where the cooling performance is required.

The example embodiments of the present disclosure have been described above. Note that the scope of the present disclosure is not limited to the above example embodiments. The present disclosure can be implemented by making various changes to the above-described example embodiments without departing from the gist of the disclosure. The matters described in the above example embodiments can be optionally combined together, as appropriate, as long as there is no inconsistency.

For example, the fins are not limited to the stacked fins, and may be configured of pin fins protruding in a columnar shape from the base portion to one side in the third direction. In this case, the top plate portion may be fixed at one end in the third direction of the pin fin.

As described above, a cooling device according to one aspect of the present disclosure is a cooling device including a heat dissipator and a liquid cooling jacket.

The heat dissipator includes
a base portion in a plate shape, the base portion extending in a first direction along a direction in which a refrigerant flows and in a second direction orthogonal to the first direction and having a thickness in a third direction orthogonal to the first direction and the second direction;
a fin protruding from the base portion toward one side in the third direction; and
a top plate portion provided at an end on the one side in the third direction of the fin.

The liquid cooling jacket includes:
a top surface located on one side in the third direction of the top plate portion with a gap in the third direction between the top surface and the top plate portion; and
a top surface recess recessed from the top surface toward the one side in the third direction, a plurality of the top surface recesses being arranged side by side in the first direction (first configuration).

Further, in the first configuration, the top surface recess may be configured as a groove extending in the second direction (second configuration).

Further, in the first configuration, the top surface recess may be configured in a circular shape as viewed in the third direction (third configuration).

Further, in any of the first to third configurations, the depth in the third direction of the top surface recess may be longer than the width in the first direction of the top surface recess (fourth configuration).

Further, in any of the first to fourth configurations, a top plate recess recessed from a surface on one side in the third direction of the top plate portion toward the other side in the third direction may be provided, and a plurality of the top plate recesses may be arranged side by side in the first direction, and
the top plate recess may be located at a position facing a turbulent flow region, generated by the top surface recess, in the third direction (fifth configuration).

Further, in any of first to fifth configurations, the fin may include a plate-shaped side plate portion extending in the first direction and the third direction and having a thickness in the second direction, and
the top plate portion may be bent in the second direction at an end on the one side in the third direction of the side plate portion (sixth configuration).

Further, in the sixth configuration, the heat dissipator may include a fin group in which the fins are arranged side by side in the second direction, and
the liquid cooling jacket may include
a side wall portion facing the side plate portions, located at both ends in the second direction of the fin group, in the second direction; and
a plurality of side wall recesses recessed in the second direction in the side wall portion and arranged side by side in the first direction (seventh configuration).

Further, In the sixth or seventh configuration, the fin may include a spoiler protruding from the side plate portion in the second direction (eighth configuration).

The present disclosure can be used for cooling various heating elements.

Features of the above-described example embodiments and the modifications thereof may be combined appropriately as long as no conflict arises.

While example embodiments of the present disclosure have been described above, it is to be understood that variations and modifications will be apparent to those skilled in the art without departing from the scope and spirit of the present disclosure. The scope of the present disclosure, therefore, is to be determined solely by the following claims.

What is claimed is:

1. A cooling device comprising:
a heat dissipator; and
a liquid cooling jacket; wherein
the heat dissipator includes:
a base portion in a plate shape, the base portion extending in a first direction along a direction in which a refrigerant flows and in a second direction orthogonal to the first direction and having a thickness in a third direction orthogonal to the first direction and the second direction;
a fin protruding from the base portion toward one side in the third direction; and
a top plate portion provided at an end on the one side in the third direction of the fin; and
the liquid cooling jacket includes:
a top surface located on the one side in the third direction of the top plate portion with a gap in the third direction between the top surface and the top plate portion; and
a top surface recess recessed from the top surface toward the one side in the third direction, a plurality of the top surface recesses being arranged side by side in the first direction.

2. The cooling device according to claim 1, wherein the top surface recess is defined by a groove extending in the second direction.

3. The cooling device according to claim 1, wherein the top surface recess has a circular shape as viewed in the third direction.

4. The cooling device according to claim 1, wherein a depth in the third direction of the top surface recess is longer than a width in the first direction of the top surface recess.

5. The cooling device according to claim 1, further comprising:
a top plate recess recessed from a surface on the one side in the third direction of the top plate portion toward the other side in the third direction, a plurality of the top plate recesses being arranged side by side in the first direction;
wherein the top plate recess is located at a position opposing a turbulent flow region, generated by the top surface recesses, in the third direction.

6. The cooling device according to claim 1, wherein
the fin includes a side plate portion in a plate shape, the side plate portion extending in the first direction and the third direction and having a thickness in the second direction; and
the top plate portion is bent in the second direction at an end on the one side in the third direction of the side plate portion.

7. The cooling device according to claim 6, wherein
the heat dissipator includes a fin group in which the fins are arranged side by side in the second direction; and
the liquid cooling jacket includes:
a side wall portion opposing the side plate portions, located at two ends of the fin group in the second direction, in the second direction; and
a side wall recess recessed in the second direction in the side wall portion, a plurality of the side wall recesses being arranged side by side in the first direction.

8. The cooling device according to claim 6, wherein the fin includes a spoiler protruding in the second direction from the side plate portion.
